(19) United States
(12) Patent Application Publication
(10) Pub. No.: US 2025/0076719 A1
(43) Pub. Date: Mar. 6, 2025

(54) ELECTRO-OPTICAL DEVICE AND ELECTRONIC APPARATUS

(71) Applicant: SEIKO EPSON CORPORATION, Tokyo (JP)

(72) Inventors: Tetsuaki MUROHASHI, FUJIMI-MACHI (JP); Shogo TAKAHASHI, CHINO-SHI (JP); Shuji TERADA, MATSUMOTO-SHI (JP); Masayuki WADA, NAGANO-SHI (JP)

(73) Assignee: SEIKO EPSON CORPORATION, Tokyo (JP)

(21) Appl. No.: 18/815,856

(22) Filed: Aug. 27, 2024

(30) Foreign Application Priority Data
Aug. 28, 2023 (JP) 2023-137856

(51) Int. Cl. G02F 1/1362; G02F 1/1368; H01L 27/12; H01L 29/786

(52) U.S. Cl. CPC G02F 1/136286; G02F 1/136213; G02F 1/1368; H10D 30/6731; H10D 30/6745; H10D 86/421; H10D 86/441; H10D 86/481; H10D 86/60

(57) ABSTRACT

A liquid crystal device includes: a TFT; a pixel electrode; a first capacitance element; a third relay electrode extending along an X-axis and including a main body portion electrically connected to the TFT through a first contact hole and also including a protruding portion protruding from the main body portion in a +Y direction and electrically connected to the pixel electrode through a second contact hole; and a common wiring line including a main body portion extending along a Y-axis and also including a protruding portion protruding from the main body portion in a −X direction and electrically connected to the first capacitance element through a third contact hole. The third relay electrode and the common wiring line each includes a first layer, and a second layer having lower light reflectance. The second layer is not provided in a portion of the main body portion of the common wiring line.

The present application is based on, and claims priority from JP Application Serial Number 2023-137856, filed Aug. 28, 2023, the disclosure of which is hereby incorporated by reference herein in its entirety.

### BACKGROUND

### 1. Technical Field

The present disclosure relates to an electro-optical device and an electronic apparatus.

### 2. Related Art

Typically, as one of electro-optical devices, there is known an active drive type liquid crystal device including a transistor configured to perform switching control to a pixel electrode, and the transistor is provided for each pixel. Such a liquid crystal device is provided with a contact hole used to connect various types of wiring lines or electrodes or the like. For example, JP-A-2005-242296 discloses an electro-optical device. This electro-optical device includes a contact hole used to connect a shield layer and a relay layer for the shield layer, and also includes a contact hole used to connect a third relay electrode and a second relay electrode.

However, the electro-optical device described in JP-A-2005-242296 has a problem in that it is difficult to improve an aperture ratio. Specifically, the shield layer is recessed in a flat surface manner, and the third relay electrode and the contact hole are disposed there. The third relay electrode is electrically connected to the pixel electrode through the contact hole. In recent years, in order to further improve the aperture ratio of the liquid crystal device, the wiring lines tend to be narrower, and the areas thereof tend to reduce. Thus, with the mode in which the shield layer is recessed, it is difficult to secure a space for disposing the contact hole and the like.

In addition, there is also a problem in which it is difficult to improve the reliability of electrical connecting at the contact hole. Specifically, a single layer structure made of a conductor such as aluminum or the like is used for the contact hole used to connect the shield layer and the relay layer for the shield layer, and also for the contact hole used to connect the third relay electrode and the second relay electrode. When a wiring line made of aluminum is formed at these contact holes, aluminum is more likely to be etched with a stripper liquid in the patterning process. Adhesion tends to deteriorate at the inside of the contact hole, and the layer of aluminum tends to be thin. Thus, when aluminum is etched, there is a possibility of deteriorating the reliability of electrical connecting.

Furthermore, when a stacking structure is employed for the entire region of each of the contact hole, the shield layer, and the third relay electrode described above, there is a problem in that heat is more likely to be generated within the substrate due to an electrolytic-corrosion preventing layer made of titanium nitride or the like having high efficiency of light absorption. That is, it is desired for an electro-optical device having the reduced heat generation within the substrate while improving the aperture ratio as well as the reliability of electrical connecting at the contact hole.

### SUMMARY

An electro-optical device includes a transistor, a pixel electrode provided to correspond to the transistor, a capacitance element provided so as to correspond to the pixel electrode, a relay layer including a main body portion and a protruding portion, the main body portion extending along a first direction, the main body portion being electrically connected to the transistor through a first contact hole, the protruding portion protruding from the main body portion in a second direction intersecting the first direction, the protruding portion being electrically connected to the pixel electrode through a second contact hole, and a first wiring line provided in a layer equal to the relay layer and including a main body portion and a protruding portion, the main body portion extending along the second direction, the protruding portion protruding from the main body portion in the first direction, the protruding portion being electrically connected to the capacitance element through a third contact hole, in which the relay layer and the first wiring line each includes a first layer having light reflectivity, and a second layer having light reflectance lower than the first layer and stacked at the first layer, and the second layer is not provided in at least a portion of the main body portion of the first wiring line.

An electronic apparatus includes the electro-optical device described above.

### BRIEF DESCRIPTION OF THE DRAWINGS

FIG. 1 is a schematic plan view illustrating a configuration of a liquid crystal device according to a first embodiment.

FIG. 2 is a schematic cross-sectional view illustrating a structure of the liquid crystal device at the line segment A-A′ in FIG. 1.

FIG. 3 is an equivalent circuit diagram illustrating an electrical configuration of the liquid crystal device.

FIG. 4 is a schematic plan view illustrating the arrangement of pixels.

FIG. 5 is a cross-sectional view illustrating a structure of an element substrate at the line segment β1-β2 in FIG. 4.

FIG. 6 is a cross-sectional view illustrating a structure of an element substrate at the line segment α1-α2 in FIG. 4.

FIG. 7 is a cross-sectional view illustrating a structure of an element substrate at the line segment γ1-γ2 in FIG. 4.

FIG. 8 is a plan view illustrating the configuration of common wiring lines and third relay electrodes.

FIG. 9 is a plan view illustrating a mode of a third relay electrode according to a second embodiment.

FIG. 10 is a cross-sectional view illustrating a structure of an element substrate at the line segment β1-β2 in FIG. 4.

FIG. 11 is a cross-sectional view illustrating a structure of an element substrate at the line segment α1-α2 in FIG. 4.

FIG. 12 is a schematic view illustrating the configuration of a projection-type display apparatus according to a third embodiment.

### DESCRIPTION OF EMBODIMENTS

Below, embodiments according to the present disclosure will be described with reference to the drawings. The present disclosure is not limited to the following embodiments. Various types of modification examples that are implemented are also included in the present disclosure within a range in which the main points of the present disclosure do not change.

In the following individual drawings, X, Y, and Z axes that represent coordinate axes perpendicular to each other are attached as necessary, and directions indicated by arrows are each set as the + direction, and directions opposite from the + direction are each set as the-direction. The +Z direction is also referred to as an upward side, and the −Z direction is also referred to as a downward side. In the present specification, a first direction represents a direction along the X-axis, and a second direction intersecting the first direction represents a direction along the Y-axis. In the following individual drawings, the scales of each layer and each member differ from those of actual layers and members in order to make each layer or each member have a recognizable size.

In addition, the plane including the X-axis and the Y-axis is also referred to as a XY plane, and a view of the XY plane as viewed from the +Z direction is also referred to as plan view or a planar view. In addition, for example, with respect to a substrate, the expression “on a substrate” indicates any one of a case in which an object is disposed on the substrate in a contact manner, a case in which an object is disposed on the substrate with another structure being interposed between them, or a case in which a portion of an object is disposed on the substrate in a contact manner and a portion of the object is disposed with another structure being interposed between them.

### 1. First Embodiment

As an example of an electro-optical device, the present embodiment describes an active-drive type liquid crystal device 100 including a thin film transistor (hereinafter referred to as a “TFT”) serving as a transistor and provided for each pixel. The liquid crystal device 100 is favorably used as an optical modulation element (liquid crystal light valve) of a projection-type display apparatus serving as an electronic apparatus that will be described later, for example.

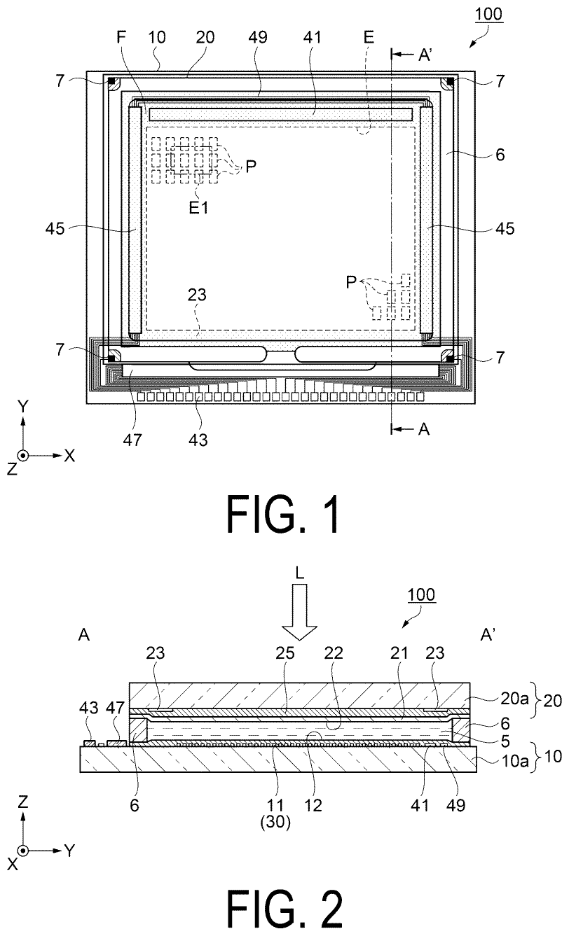

As illustrated in FIGS. 1 and 2, the liquid crystal device 100 serving as an electro-optical device according to the present embodiment includes an element substrate 10, a counter substrate 20 disposed so as to be opposed to the element substrate 10, and a liquid crystal layer 5 including a liquid crystal interposed between the element substrate 10 and the counter substrate 20.

A substrate such as a glass substrate or a quartz substrate is used for a substrate 10a of the element substrate 10, for example. A transparent substrate such as a glass substrate or a quartz substrate is used for a substrate 20a of the counter substrate 20, for example.

The element substrate 10 is greater than the counter substrate 20 in a planar view. The element substrate 10 and the counter substrate 20 are bonded through a seal material 6 disposed along the outer edge of the counter substrate 20. A liquid crystal having positive or negative dielectric anisotropy is incorporated in a space between the element substrate 10 and the counter substrate 20 to provide the liquid crystal layer 5. In the following description, the element substrate 10 and the counter substrate 20 are also referred to as a pair of substrates.

An adhesive such as thermosetting, light curable, electron-beam curable epoxy resin is used for the seal material 6, for example. A spacer (not illustrated) is mixed with the seal material 6 in order to maintain a constant distance between a pair of substrates.

A display region E including a plurality of pixels P arrayed in a matrix manner is provided at the inside of the seal material 6. A peripheral area F is provided at the outside of the display region E. A partition portion 23 is provided in the peripheral area F and between the seal material 6 and the display region E so as to surround the display region E. Metal or metallic oxide having a light shielding property is used for the partition portion 23.

Although illustration is not given, a dummy region is provided around the display region E, and a light shielding section is provided in the display region E. The dummy region does not contribute to displaying performed by the liquid crystal device 100. The light shielding section is a so-called black matrix, and is provided in the counter substrate 20.

A terminal section in which a plurality of external connection terminal 43 are arrayed is provided at the element substrate 10. A data-line driving circuit 47 is provided between the first side along the terminal section and the seal material 6. In addition, an inspection circuit 41 is provided between the display region E and the seal material 6 along the second side opposed from the first side.

A scanning-line drive circuit 45 is provide between the display region E and the seal material 6 along the third side and the fourth side that are perpendicular to the first side and are opposed to each other. A plurality of wiring lines 49 configured to connect two scanning-line drive circuits 45 is provided between the inspection circuit 41 and the seal material 6 at the second side.

The data-line driving circuit 47 and the wiring lines 49 connected to the scanning-line drive circuit 45 are electrically connected to the plurality of external connection terminals 43 arrayed along the first side. Note that the arrangement of the inspection circuit 41 is not limited to that described above, and the inspection circuit 41 may be provided between the display region E and the seal material 6 along the data-line driving circuit 47.

As illustrated in FIG. 2, a light-transmitting pixel electrode 11, a TFT 30 serving as a switching element, the wiring lines 49, and an alignment film 12 configured to cover these items are provided for each pixel P at the front surface, at the liquid crystal layer 5 side, of the substrate 10a. The TFT 30 and the pixel electrode 11 are constituent elements of the pixel P. The pixel electrode 11 is provided so as to correspond to the TFT 30. The element substrate 10 includes the substrate 10a, the pixel electrode 11 provided at the substrate 10a, the TFT 30, the wiring lines 49, and the alignment film 12.

Light L enters the liquid crystal device 100 from the counter substrate 20 side. The light L comes from a laser light source, for example. Note that a direction in which the light L enters the liquid crystal device 100 is not limited to the counter substrate 20 side, and the light L may enters from the element substrate 10 side. In addition, the liquid crystal device 100 may be configured to include a light collecting unit such as a microlens configured to collect the incident light L for each pixel P.

At the front surface, at the liquid crystal layer 5 side, of the substrate 20a, there is provided the partition portion 23, an insulating layer 25 covering the partition portion 23 and formed into a film, a counter electrode 21 provided so as to cover the insulating layer 25, and an alignment film 22 provided so as to cover the counter electrode 21. Note that the liquid crystal device 100 is configured such that a common electrode is disposed at the counter substrate 20 side as the counter electrode 21. However, the liquid crystal device 100 is not limited to this configuration.

As illustrated in FIG. 1, the scanning-line drive circuit 45 and the inspection circuit 41 overlap with the partition portion 23 in a planar view. The partition portion 23 functions as a light shielding section. Specifically, the partition portion 23 blocks light such that the light L described above entering from the counter substrate 20 side does not enter a peripheral circuit such as the scanning-line drive circuit 45. That is, the partition portion 23 has a function of preventing a malfunction of peripheral circuits. In addition, the partition portion 23 also suppresses entrance of unnecessary stray light into the display region E. This makes it possible to suppress a reduction in the contrast of the liquid crystal device 100.

With reference back to FIG. 2, the insulating layer 25 is configured to cover the partition portion 23 and is provided so as to flatten the front surface of the liquid crystal layer 5 side. The insulating layer 25 is formed of an inorganic material such as silicon oxide having optical transparency, for example.

The counter electrode 21 is configured to cover the insulating layer 25, and is electrically connected to an up-down conductive section 7 provided at four corners of the counter substrate 20. The up-down conductive section 7 is electrically connected to a common wiring line 18, which will be described later, at the element substrate 10 side.

The pixel electrode 11 and the counter electrode 21 are comprised of a transparent conductive film made of indium tin oxide (ITO), indium zinc oxide (IZO), or the like, for example. The alignment film 12 and the alignment film 22 are selected on the basis of optical design of the liquid crystal device 100. The material of the alignment film 12, 22 includes an inorganic alignment film made of silicon oxide or the like and an organic alignment film made of polyimide or the like.

The optical design of a normally white mode or normally black mode is employed for the liquid crystal device 100. In the normally white mode, the transmittance of a pixel P when no voltage is applied is larger than the transmittance when a voltage is applied. In the normally black mode, the transmittance of a pixel P when no voltage is applied is smaller than the transmittance when a voltage is applied. In the liquid crystal device 100, a polarizing element is disposed at each of the side at which the light L enters and the side at which the light L outputs, depending on the optical design.

The present embodiment describes an example in which the inorganic alignment film described above is used as the alignment film 12, 22, a liquid crystal having negative dielectric anisotropy is used, and the optical design of the normally black mode is employed.

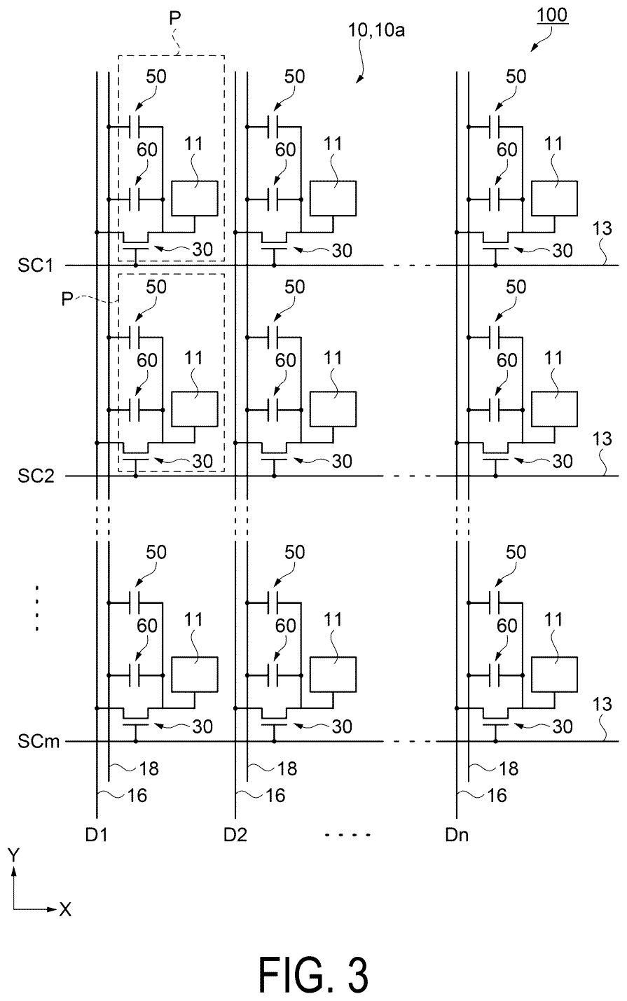

As illustrated in FIG. 3, the liquid crystal device 100 includes a scanning line 13, a data line 16, and a common wiring line 18 provided at the substrate 10a of the element substrate 10. The scanning line 13 extends along the X-axis. The data line 16 and the common wiring line 18 extend along the Y-axis. The common wiring line 18 is not limited to that extending along the Y-axis. The common wiring line 18 serves as one example of a first wiring line.

A region separated by the scanning line 13 extending along the X-axis and the data line 16 extending along the Y-axis is a pixel P. The pixel P includes the pixel electrode 11, the TFT 30, a first capacitance element 50, and a second capacitance element 60. The first capacitance element 50 and the second capacitance element 60 are provided so as to correspond to the pixel electrode 11.

The scanning line 13 is electrically connected to the gate of the TFT 30. The data line 16 is electrically connected to the source of the TFT 30. The scanning line 13 has a function of collectively controlling turning on and off the TFT 30 provided in the same row. The pixel electrode 11 is electrically connected to the drain of the TFT 30.

The data line 16 is electrically connected to the data-line driving circuit 47, and supplies the pixel P with an image signal D1, D2, . . . , Dn supplied from the data-line driving circuit 47. The scanning line 13 is electrically connected to the scanning-line drive circuit 45, and supplies each pixel P with a scanning signal SC1, SC2, . . . , SCm supplied from the scanning-line drive circuit 45.

The image signal D1 to the image signal Dn supplied from the data-line driving circuit 47 to the data line 16 may be supplied in a line-sequential manner in this order, or may be supplied, on a group-by-group basis, to a plurality of data lines 16 adjacent to each other. The scanning-line drive circuit 45 supplies the scanning line 13 with the scanning signal SC1 to the scanning signal SCm at predetermined timing in a pulse form on a line-sequential manner.

Upon the scanning signal SC1 being inputted into the TFT 30, the TFT 30 is brought into the ON state for a predetermined period of time. In this manner, the image signal D1 supplied from the data line 16 is written in the pixel electrode 11 at predetermined timing. In addition, the image signal D1 at a predetermined level written in the liquid crystal layer 5 through the pixel electrode 11 is held for a certain period of time between the pixel electrode 11 and the counter electrode 21 disposed so as to be opposed to each other with the liquid crystal layer 5 being interposed between them.

In order to prevent the held image signal D1 from leaking, the first capacitance element 50 and the second capacitance element 60 are electrically connected in parallel with respect to a liquid crystal capacitor provided between the pixel electrode 11 and the counter electrode 21. One end of the first capacitance element 50 is electrically connected to the drain of the TFT 30 and the pixel electrode 11. The other end of the first capacitance element 50 is electrically connected to the common wiring line 18 to which a constant potential is applied. The second capacitance element 60 is connected in a manner similar to the first capacitance element 50.

Here, although illustration is not given, the inspection circuit 41 is connected to the data line 16. During the process of manufacturing the liquid crystal device 100, this makes it possible to detect the image signals D1, D2, . . . , and Dn to check operational malfunction or the like of the liquid crystal device 100.

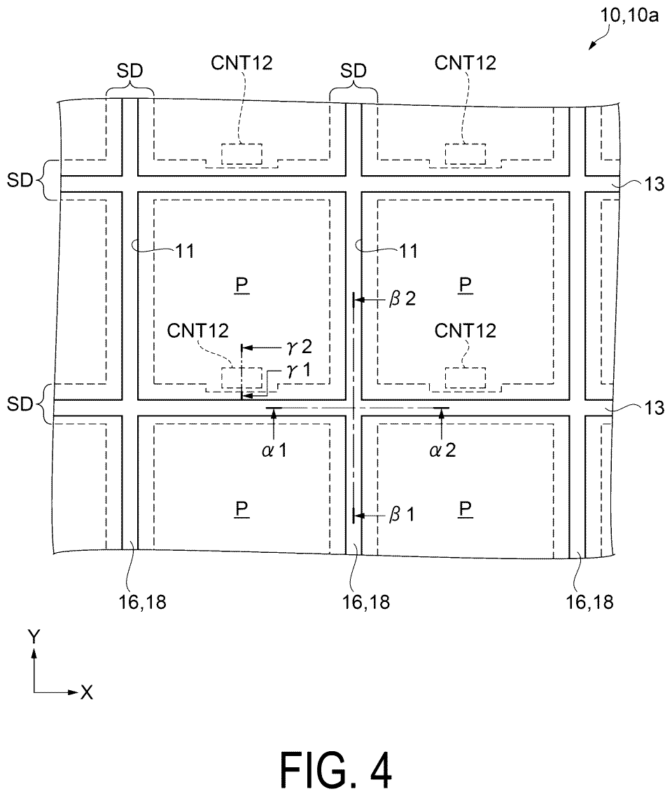

As illustrated in FIG. 4, the pixel electrode 11 has a substantially square shape, and there are a plurality of pixel electrodes 11 provided in a matrix manner so as to correspond to the arrangement of pixels P. Between adjacent pixel electrodes 11, the scanning line 13 is provided along the X-axis, and the data line 16 and the common wiring line 18 are provided along the Y-axis. Note that, in FIG. 4, illustration is made such that a region E1 that is a portion of the display region E in FIG. 1 is enlarged.

In the display region E, a plurality of pixels P are divided in a planar view to provide a light shielding region SD. The light shielding region SD includes a straight-shaped portion including the scanning line 13, and a straight-shaped portion including the data line 16 and the common wiring line 18, and has a lattice form as illustrated with the dashed line. An electrically conductive member having a light shielding property is used for the functional layers and wiring lines such as the scanning line 13 and the data line 16, and hence, the light shielding region SD is a so-called non-open area. That is, in the display region E, a region except for the light shielding region SD is an opening area.

A second contact hole CNT12 is provided in an end portion, at the −Y direction, of the light shielding region SD so as to correspond to the pixel electrode 11. The pixel electrode 11 and a third relay electrode 83 that will be described later are electrically connected to each other through the second contact hole CNT12. That is, in the present embodiment, the third relay electrode 83 corresponds to a third relay electrode of a typical electro-optical device.

In the liquid crystal device 100, the second contact hole CNT12 is provided in the light shielding region SD. That is, the scanning line 13 and the common wiring line 18 are not recessed in a planar view, and hence, it is possible to further reduce the width of these wiring lines, which makes it possible to easily improve the aperture ratio. Detailed configuration of the element substrate 10 including the third relay electrode 83 and the like will be described later.

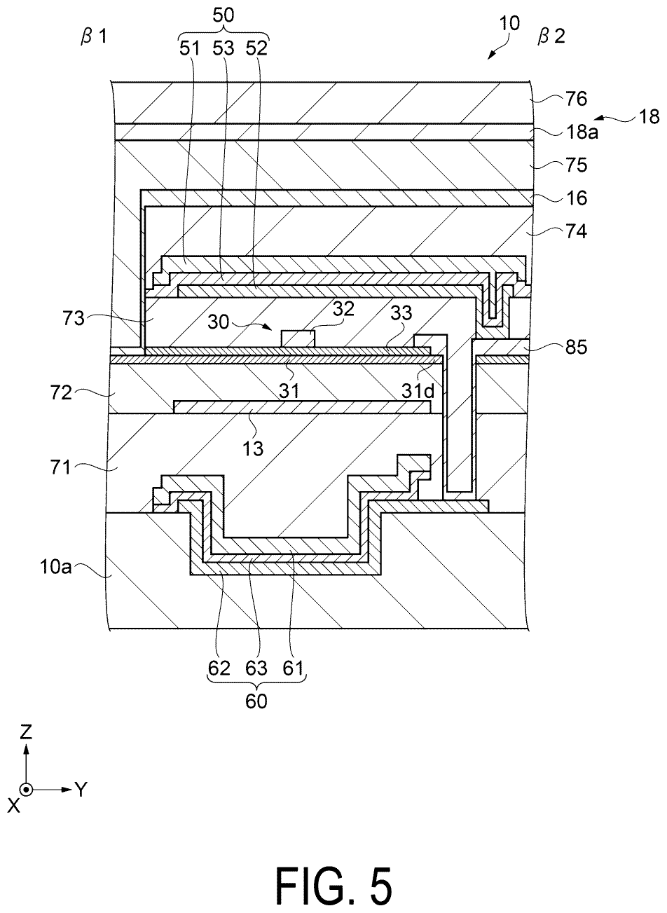

As illustrated in FIGS. 5, 6, and 7, the element substrate 10 of the liquid crystal device 100 includes the substrate 10a, the second capacitance element 60, the scanning line 13, the TFT 30 including a semiconductor layer 31 and a gate electrode 32, the first capacitance element 50, the data line 16, the common wiring line 18, the third relay electrode 83, the pixel electrode 11, and a plurality of interlayer insulating layers that will be described later. Note that the third relay electrode 83 serves as one example of a relay layer of the present disclosure.

The element substrate 10 has a configuration in which a plurality of functional layers are stacked at the substrate 10a serving as a base. Specifically, at the substrate 10a, there are stacked, in this order, a first conductive layer including a fourth capacitance electrode 62 of the second capacitance element 60, a second conductive layer including a third capacitance electrode 61 of the second capacitance element 60, a third conductive layer including the scanning line 13, the semiconductor layer 31 of the TFT 30, a fourth conductive layer including the gate electrode 32 of the TFT 30, a fifth conductive layer including a second capacitance electrode 52 of the first capacitance element 50, a sixth conductive layer including a first capacitance electrode 51 of the first capacitance element 50, a seventh conductive layer including the data line 16, an eighth conductive layer of the common wiring line 18, and the pixel electrode 11.

A second dielectric layer 63 is provided between the fourth capacitance electrode 62 of the first conductive layer and the third capacitance electrode 61 of the second conductive layer. A first interlayer insulating layer 71 is provided between the second conductive layer and the third conductive layer. A second interlayer insulating layer 72 is provided between the third conductive layer and the semiconductor layer 31. A gate insulation layer 33 is provided between the fourth conductive layer of the semiconductor layer 31 and the gate electrode 32. A third interlayer insulating layer 73 serving as a second insulating layer is provided between the fourth conductive layer and the fifth conductive layer.

A first dielectric layer 53 is provided between the fifth conductive layer and the sixth conductive layer. A fourth interlayer insulating layer 74 serving as a first insulating layer is provided between the sixth conductive layer and the seventh conductive layer. A fifth interlayer insulating layer 75 is provided between the seventh conductive layer and the eighth conductive layer. The sixth interlayer insulating layer 76 is provided between the eighth conductive layer and the pixel electrode 11.

The materials of these interlayer insulating layers include silicon oxide (None-doped Silicate Glass: NSG) or silicon nitride or the like, for example. In the present embodiment, silicon oxide is employed.

The second capacitance element 60 is provided at the substrate 10a and also inside of a trench that is not illustrated in the drawing. The second capacitance element 60 is configured such that the fourth capacitance electrode 62, the second dielectric layer 63, and the third capacitance electrode 61 are stacked in the order from the substrate 10a side. The materials of the third capacitance electrode 61 and the fourth capacitance electrode 62 include electrically conductive polysilicon, for example. A dielectric material is used for the material of the second dielectric layer 63. For example, the dielectric material includes silicon nitride, silicon oxide, hafnium oxide, aluminum oxide, tantalum oxide, or the like, and these layers are used as a single layer or as a combination of them.

The scanning line 13 also functions as a light shielding layer, and is provided at the first interlayer insulating layer 71. A known material having a light shielding property and electrically conductive property is used for the scanning line 13. The scanning line 13 has a function of blocking the light L entering the semiconductor layer 31 mainly from below. In the present embodiment, tungsten silicide is used as the material of the scanning line 13.

The TFT 30 includes the semiconductor layer 31 provided at the second interlayer insulating layer 72, the gate insulation layer 33, and the gate electrode 32 at the third interlayer insulating layer 73. The gate electrode 32 is electrically connected to the scanning line 13.

The semiconductor layer 31 of the TFT 30 is provided with a lightly doped drain (LDD) structure. The semiconductor layer 31 is made of electrically conductive polysilicon, for example. The gate electrode 32 is made of electrically conductive polysilicon, for example. The semiconductor layer 31 extends along the Y-axis.

The first capacitance element 50 is provided at the third interlayer insulating layer 73. The first capacitance element 50 is configured such that the second capacitance electrode 52, the first dielectric layer 53, and the first capacitance electrode 51 are stacked in the order from the substrate 10a side. The materials of the first capacitance electrode 51 and the second capacitance electrode 52 include electrically conductive polysilicon, for example. A dielectric material similar to that of the second capacitance element 60 is used as the material of the first dielectric layer 53.

The data line 16 is provided at the fourth interlayer insulating layer 74, and extends along the Y-axis. There is no particular limitation as to the material of the data line 16 as long as the material is a low-resistance wiring line material having electrical conductivity, and the material of the data line 16 includes a metal such as aluminum or titanium, or a metallic compound of these metal, for example. The data line 16 is electrically connected to a source-drain region of the semiconductor layer 31.

The common wiring line 18 and the third relay electrode 83 are provided in the same layer at the fifth interlayer insulating layer 75. The common wiring line 18 and the third relay electrode 83 are electrically connected to the counter electrode 21 described above, and are supplied with a common potential. The materials of the common wiring line 18 and the third relay electrode 83 include a metal such as aluminum or titanium, or a metallic compound of these metals, for example. In the liquid crystal device 100, a stacking structure is employed for the common wiring line 18 and the third relay electrode 83.

Specifically, the common wiring line 18 includes a first layer 18a having light reflectivity, and also includes a second layer 18b stacked at the first layer 18a and having light reflectance lower than the first layer 18a. The third relay electrode 83 includes a first layer 83a having light reflectivity, and also includes a second layer 83b stacked at the first layer 83a and having light reflectance lower than the first layer 83a.

The first layers 18a and 83a include aluminum. The second layers 18b and 83b include titanium nitride. Specifically, in the present embodiment, aluminum is employed for the first layers 18a and 83a, and titanium nitride is employed for the second layers 18b and 83b. Titanium nitride has a function of suppressing electrolytic corrosion with or oxidation of aluminum of the first layers 18a and 83a, and also has a function of protecting the first layers 18a and 83a from a stripper liquid used in the manufacturing process. On the other hand, aluminum has favorable electrical conductivity. In addition, aluminum has light reflectance higher than titanium nitride. Furthermore, in a region that does not require the functions described above, the second layer 18b or 83b is not provided, and the light L is reflected to achieve a function of suppressing generation of heat within the element substrate 10.

Here, when the films are formed using a sputtering method, the light reflectance of aluminum is approximately 90% in a wavelength of 550 nm in a visible range, and the light reflectance of titanium nitride is approximately 25%, for example. The light reflectance of such a base material can be measured using a spectro photometer or the like. Note that, in the present specification, the “having light reflectivity” means that the light reflectance described above is approximately 50% or more. With this configuration, by actively reflecting light to prevent light absorption, it is possible to suppress generation of heat in the liquid crystal device 100.

When the element substrate 10 is seen in plan view, the area of the second layer 18b, 83b is smaller than the area of the corresponding first layer 18a, 83a. That is, the second layers 18b, 83b are each stacked at a portion of the region of the corresponding first layer 18a, 83a, rather than being stacked at the whole of the corresponding first layer 18a, 83a. Details of the common wiring line 18 and the third relay electrode 83 will be described later.

The pixel electrode 11 is provided at the sixth interlayer insulating layer 76. Although illustration is not given, the alignment film 12 is provided so as to cover the pixel electrode 11. The alignment film 12 of the element substrate 10 and the alignment film 22 and the counter substrate 20 described above are each comprised of a collective body having a column shape obtained through deposition of an inorganic material such as silicon oxide from a predetermined direction such as an oblique direction or the like to cause it to grow into a column shape.

As illustrated in FIG. 5, the second capacitance electrode 52 of the first capacitance element 50 is electrically connected to a fifth relay electrode 85 disposed at the fourth conductive layer, and the fifth relay electrode 85 is electrically connected to the fourth capacitance electrode 62 of the second capacitance element 60.

The second layer 18b is not provided in a range of the line segment β1-β2 of the common wiring line 18. The light L entering from above is reflected at the first layer 18a in a region where the second layer 18b is not stacked. Thus, in this region described above, it is possible to suppress generation of heat due to absorption of the light L.

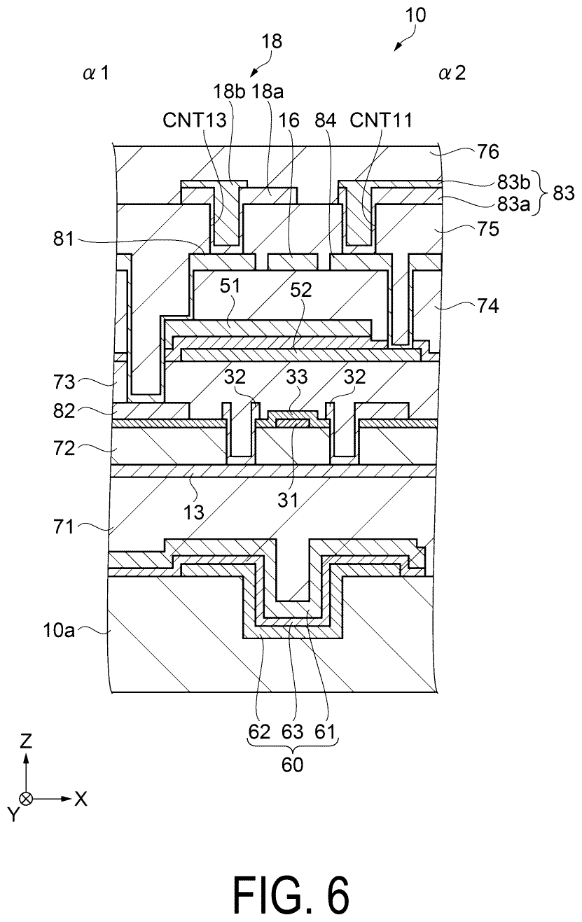

As illustrated in FIG. 6, the common wiring line 18 and the first capacitance electrode 51 of the first capacitance element 50 are electrically connected through a first relay electrode 81 disposed in the seventh conductive layer. Furthermore, the first relay electrode 81 is electrically connected to a second relay electrode 82 disposed in the fourth conductive layer.

The third relay electrode 83 is electrically connected to a fourth relay electrode 84 disposed in the seventh conductive layer. The fourth relay electrode 84 is electrically connected to the second capacitance electrode 52 of the first capacitance element 50.

In particular, in a region including a region that overlaps with a first contact hole CNT11, the third relay electrode 83 is configured such that a second layer 83b covers a first layer 83a as well as the inside of the first contact hole CNT11. With this configuration, during the manufacturing process in which the third relay electrode 83 is patterned, the first layer 83a is protected by the second layer 83b. This makes it possible to suppress etching of the first layer 83a, thereby improving the reliability of electrical connecting.

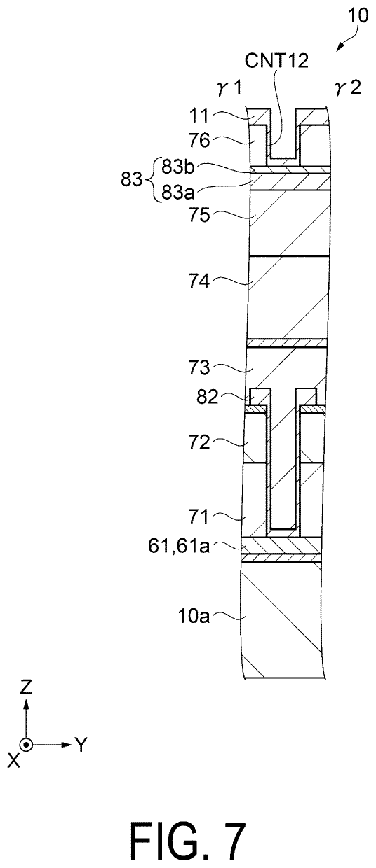

As illustrated in FIGS. 6 and 7, the first capacitance electrode 51 of the first capacitance element 50 and the third capacitance electrode 61 of the second capacitance element 60 are electrically connected to the common wiring line 18 through the first relay electrode 81 disposed in the seventh conductive layer and the second relay electrode 82 disposed in the fourth conductive layer.

In particular, in a region including a region that overlaps with a third contact hole CNT13, the common wiring line 18 is configured such that the second layer 18b is stacked at the first layer 18a only at the inside of and around the third contact hole CNT13. With this configuration, during the manufacturing process in which the common wiring line 18 is patterned, the first layer 18a is protected by the second layer 18b. This makes it possible to suppress etching of the first layer 18a, thereby improving the reliability of electrical connecting. Furthermore, at the +X direction of the third contact hole CNT13, the second layer 18b is stacked at the first layer 18a. This makes it possible to suppress reflection of the light L at the first layer 18a, thereby suppressing generation of heat within the element substrate 10.

As illustrated in FIG. 7, the second relay electrode 82 is electrically connected to the third capacitance electrode 61 of the second capacitance element 60. Specifically, although illustration is not given, the third capacitance electrode 61 includes a sticking-out section 61a that sticks out in a planar view. The second relay electrode 82 is electrically connected to this sticking-out section 61a. The second capacitance electrode 52 of the first capacitance element 50 and the fourth capacitance electrode 62 of the second capacitance element 60 are electrically connected to the pixel electrode 11 and a drain 31d of the TFT 30. Note that, instead of the first capacitance element 50, it may be possible to use a relay electrode used to electrically connect the fourth capacitance electrode 62 of the second capacitance element 60 and the drain 31d of the TFT 30.

The pixel electrode 11 is electrically connected to the third relay electrode 83 disposed in the eighth conductive layer. In particular, the pixel electrode 11 is electrically connected to the third relay electrode 83 through the second contact hole CNT12. In a region including a region where the third relay electrode 83 overlaps with the second contact hole CNT12, the third relay electrode 83 is configured such that the first layer 83a is covered by the second layer 83b. In other words, the second layer 83b exists between the pixel electrode 11 and the first layer 83a.

Here, when aluminum and ITO are electrically connected directly to each other, electrolytic corrosion is more likely to occur between them. This may lead to breakage of aluminum lines or insulation due to generation of alumina or the like. In contrast, the present embodiment is configured such that titanium nitride and ITO are connected to each other. This configuration suppresses occurrence of electrolytic corrosion in a region that includes the second contact hole CNT12, which makes it possible to improve the reliability of electrical connecting.

The signal wiring lines such as scanning line 13 and the common wiring line 18 that constitute the functional layers described above and the electrodes such as the TFT 30 and the first relay electrode 81 are provided in the light shielding region SD that separates a plurality of pixels P in a planar view.

In manufacturing of the element substrate 10, it may be possible to employ a known method applied to known semiconductor processes, which includes a low pressure chemical vapor deposition (CVD) method, an atmospheric pressure CVD method, a plasma CVD process, a photolithography method, a sputtering method, an etching method, a chemical mechanical planarization (CMP) method, and the like.

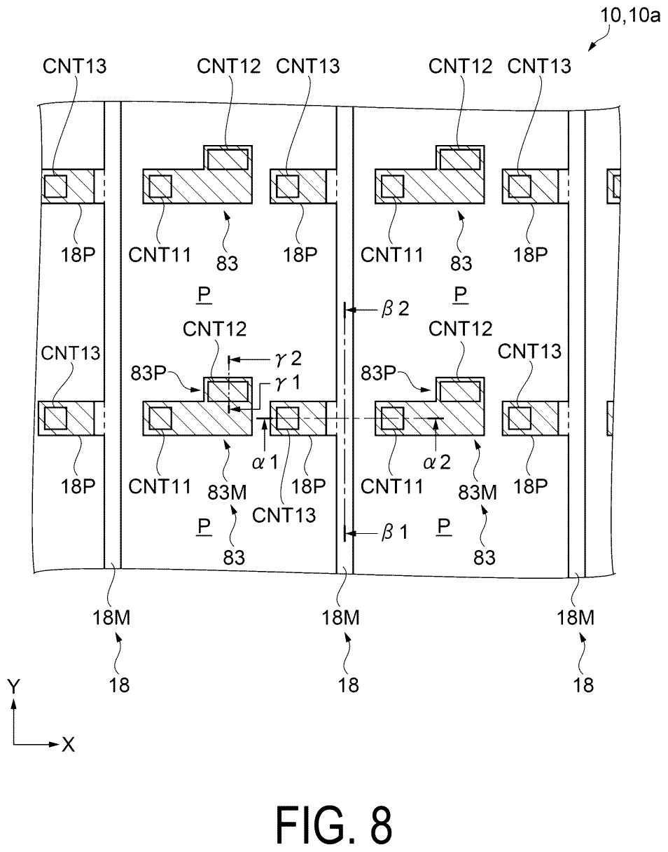

As illustrated in FIG. 8, common wiring lines 18 are arranged along the Y-axis in a stripe manner. The element substrate 10 includes a common wiring line 18 serving as a first wiring line at the center in FIG. 8, and a common wiring line 18 serving as a second wiring line adjacent in a direction along the X-axis. The third relay electrode 83 is provided between common wiring lines 18 adjacent to each other in plan view.

Note that FIG. 8 illustrates a region corresponding to FIG. 4. In addition, in the common wiring line 18, hatching is applied to a region to which the stacking structure including the first layer 18a and the second layer 18b is applied. Similarly, in the third relay electrode 83, hatching is applied to a region to which the stacking structure including the first layer 83a and the second layer 83b is applied. Furthermore, the boundary between a main body portion 18M and a protruding portion 18P, which will be described later, is illustrated with the dashed line.

The common wiring line 18 includes the main body portion 18M and the protruding portion 18P. The main body portion 18M extends in a direction along the Y-axis. The protruding portion 18P protrudes from the main body portion 18M in the −X direction.

The protruding portion 18P is configured such that the first layer 18a and the second layer 18b are provided in a region including a region that overlaps with the third contact hole CNT13 in a planar view. Specifically, the protruding portion 18P is configured such that the third contact hole CNT13 is disposed in a region including a region that overlaps, in a planar view, with the vicinity of the end portion at the −X direction of the protruding portion 18P.

The common wiring line 18 is electrically connected to the first capacitance electrode 51 of the first capacitance element 50 described above through the third contact hole CNT13.

The second layer 18b is not provided in at least a portion of the main body portion 18M. That is, in the present embodiment, the second layer 18b is not provided at the whole of the main body portion 18M in a planar view. In addition, the protruding portion 18P is configured such that the second layer 18b is not provided in a portion, at the +X direction that is the common wiring line 18 side, of the 18P.

The arrangement described above is preferable when the distance between adjacent common wiring lines 18 along the X-axis is relatively wide. That is, since the distance described above is relatively wide, the second layer 18b sufficiently achieves its function even when the area of the second layer 18b is relatively reduced at and around the third contact hole CNT13. This makes it possible to reduce an excessive second layer 18b at and around the third contact hole CNT13. Thus, in addition to an improvement in the reliability of electrical connecting at and around the third contact hole CNT13, the region where the first layer 18a is exposed increases, which makes it possible to further suppress generation of heat within the element substrate 10.

The third relay electrode 83 includes a main body portion 83M and a protruding portion 83P. The main body portion 83M has an island shape, and extends in a direction along the X-axis. The protruding portion 83P protrudes from the main body portion 83M in the +Y direction.

The third relay electrode 83 is configured such that the first layer 83a and the second layer 83b are provided in a region including a region that overlaps with the first contact hole CNT11 and the second contact hole CNT12 in a planar view. Specifically, in the main body portion 83M, the first contact hole CNT11 is disposed in a region including a region that overlaps with the end portion at the −X direction and the vicinity of this end portion in a planar view. The second contact hole CNT12 is disposed in a region including a region that overlaps with the protruding portion 83P in a planar view. In the third relay electrode 83, the entire first layer 83a in a planar view is covered with the second layer 83b.

The protruding portion 83P is electrically connected to the pixel electrode 11 described above through the second contact hole CNT12. The main body portion 83M is electrically connected to the TFT 30 described above through the first contact hole CNT11.

As for a method of forming the first layers 18a and 83a and the second layers 18b and 83b, it may be possible to employ a known technique such as a sputtering method, for example. In a direction along the Z-axis, the thickness of the first layer 18a, 83a is, for example, 0.35 μm, and the thickness of the second layer 18b, 83b is, for example, 0.15 μm.

With the present embodiment, it is possible to obtain the following effects.

It is possible to improve the aperture ratio and the reliability of electrical connecting at the first contact hole CNT11, the second contact hole CNT12, and the third contact hole CNT13, and also possible to suppress generation of heat within the element substrate 10. Specifically, the third relay electrode 83 and the pixel electrode 11 are electrically connected to each other at the second contact hole CNT12 disposed in a region including a region that overlaps with the protruding portion 83P in a planar view. This configuration makes it possible to reduce the width and the area of the main body portion 83M in a planar view, as compared with a case in which the second contact hole CNT12 is disposed in a region including a region that overlaps with the main body portion 83M of the third relay electrode 83 in a planar view. This makes it possible to improve the aperture ratio.

The protruding portions 18P and 83P are configured such that aluminum and titanium nitride are stacked. Thus, the stacking structure is also provided for the first contact hole CNT11 and the third contact hole CNT13. Thus, at the time of patterning the third relay electrode 83 and the common wiring line 18, the first layer 18a, 83a is protected by the second layer 18b, 83b, and it is possible to suppress etching of the first layers 18a and 83a. This makes it possible to improve the reliability of electrical connecting through the first contact hole CNT11 and the third contact hole CNT13.

The second layer 18b is not provided in at least a portion of the region of the common wiring line 18, that is, in a portion of the region of the body portion 18M and the protruding portion 18P. The first layer 18a is more likely to reflect the light L as compared with the second layer 18b, and hence, it is possible to suppress generation of heat within the element substrate 10 due to absorption of the light L.

The second contact hole CNT12 is provided in a region that overlaps with the protruding portion 83P of the third relay electrode 83 having the stacking structure. Thus, the second layer 83b exists between the first layer 83a and the pixel electrode 11, which makes it possible to suppress occurrence of electrolytic corrosion.

These make it possible to improve the aperture ratio and the reliability of electrical connecting at the first contact hole CNT11 and the third contact hole CNT13. Thus, it is possible to provide the liquid crystal device 100 configured to suppress generation of heat within the element substrate 10.

### 2. Second Embodiment

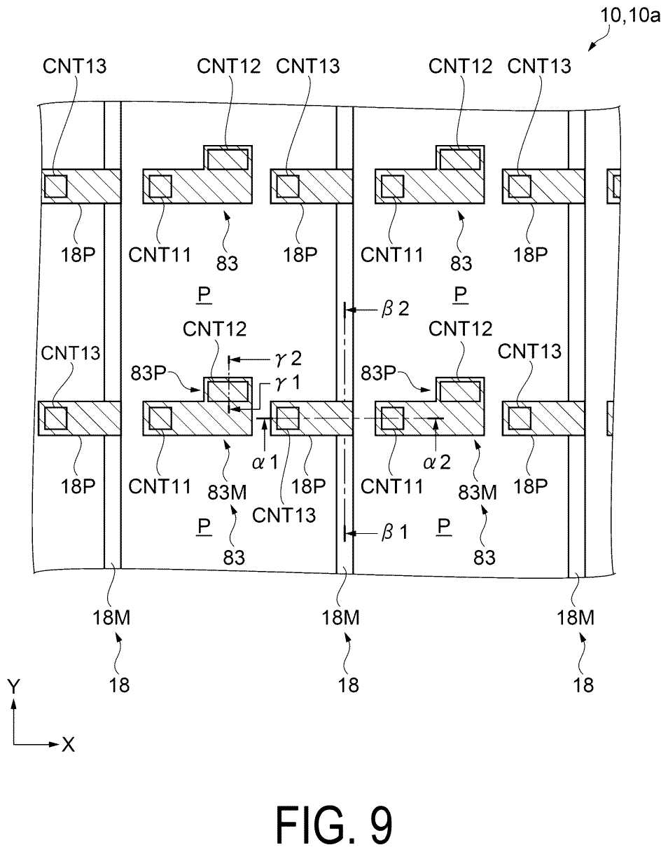

A liquid crystal device serving as an electro-optical device according to the present embodiment will be described with reference to FIGS. 9 to 11. Note that the liquid crystal device according to the second embodiment is configured such that the region where the second layer 18b of the common wiring line 18 is provided is modified from the liquid crystal device 100 according to the embodiment described above. Thus, the same reference characters are used for the same constituent portions as those in the first embodiment, and explanation thereof will not be repeated.

Note that FIG. 9 illustrates a region corresponding to FIG. 4, as in FIG. 8. In addition, in the common wiring line 18, hatching is applied to a region to which the stacking structure including the first layer 18a and the second layer 18b is applied. Similarly, in the third relay electrode 83, hatching is applied to a region to which the stacking structure including the first layer 83a and the second layer 83b is applied.

As illustrated in FIG. 9, the second layer 18b is not provided in at least a portion of the main body portion 18M. That is, in the present embodiment, the second layer 18b extends along the X-axis, and is provided in the entire region of the protruding portion 18P and in a region of a portion of the main body portion 18M in a planar view.

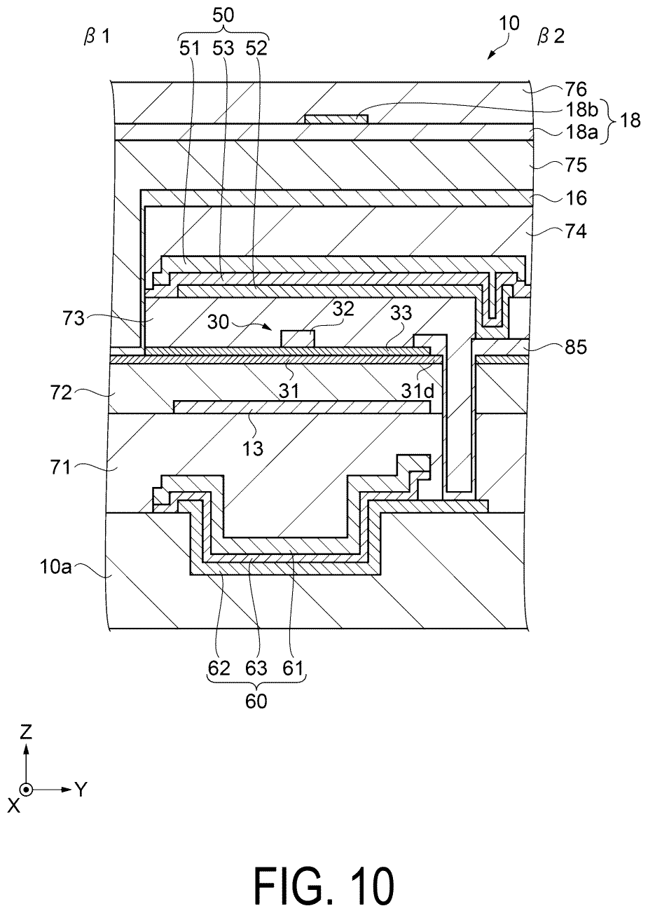

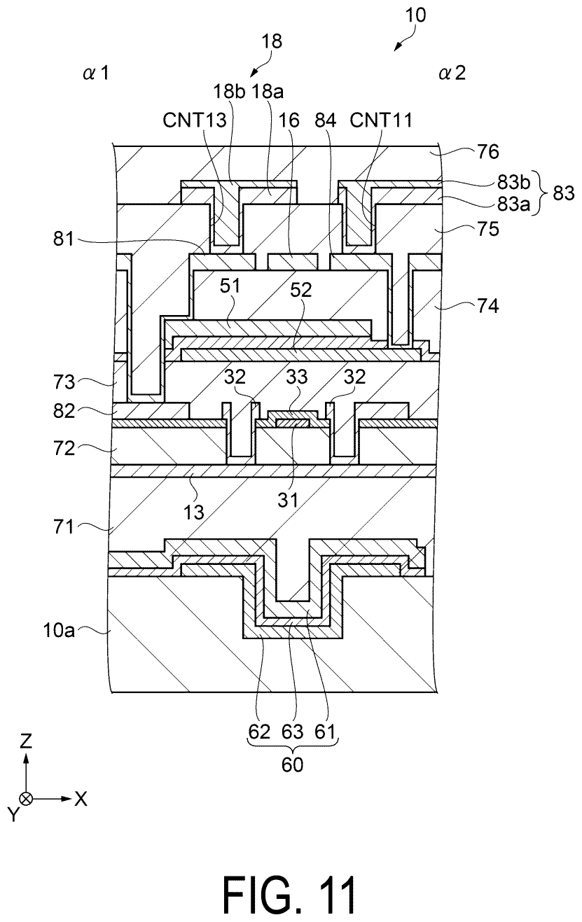

More specifically, as illustrated in FIG. 10, the second layer 18b is stacked at a portion of the first layer 18a in cross section at the line segment β1-β2. FIG. 10 illustrates a region corresponding to FIG. 5. In addition, as illustrated in FIG. 11, the entire area of the first layer 18a is covered with the second layer 18b in cross section at the line segment α1-α2. FIG. 11 illustrates a region corresponding to FIG. 6.

The arrangement described above is preferable when the distance between adjacent common wiring lines 18 along the X-axis is relatively narrow. That is, since the distance described above is relatively narrow, the area of the second layer 18b is relatively increased at and around the third contact hole CNT13, and the second layer 18b is caused to sufficiently achieve its function.

With the present embodiment, it is possible to obtain the effects similar to those of the embodiment described above.

### 3. Third Embodiment

The present embodiment describes, as an example, a projection-type display apparatus 1000 as an electronic apparatus. The liquid crystal device 100 serving as the electro-optical device according to the embodiments described above is mounted at the projection-type display apparatus 1000 according to the present embodiment. The projection-type display apparatus 1000 is a liquid crystal projector.

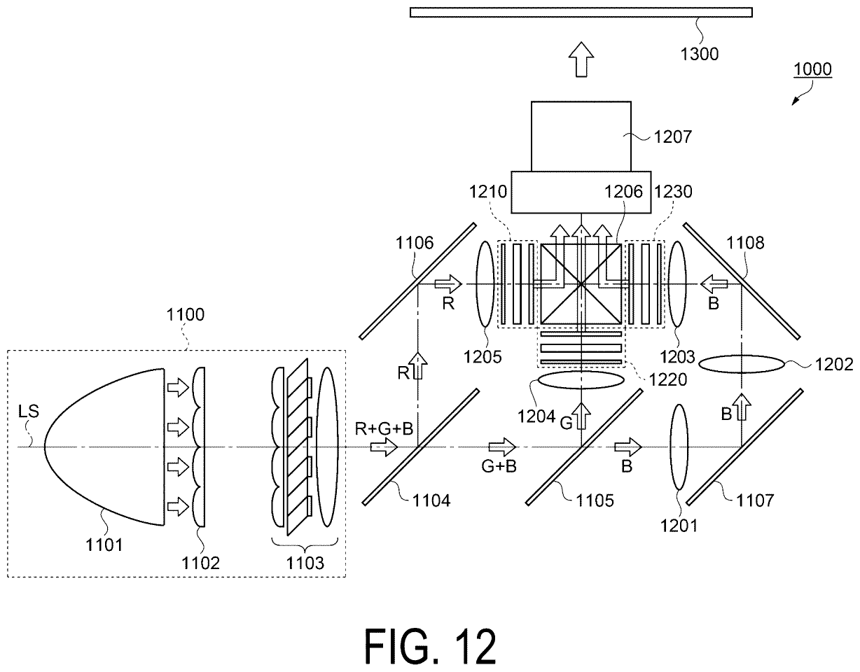

As illustrated in FIG. 12, the projection-type display apparatus 1000 includes: a polarized-light illumination device 1100 disposed along a system optical axis LS; two dichroic mirrors 1104 and 1105 serving as a light splitting element; three reflecting mirrors 1106, 1107, and 1108; five relay lenses 1201, 1202, 1203, 1204, and 1205; transmissive-type liquid-crystal light valves 1210, 1220, and 1230 serving as three optical modulation elements; a cross dichroic prism 1206 serving as a light synthesizing element; and a projection lens 1207.

The polarized-light illumination device 1100 generally includes a lamp unit 1101 serving as a light source including a white light source such as an extra-high pressure mercury lamp or a halogen lamp, an integrator lens 1102, and a polarization-light conversion element 1103.

The dichroic mirror 1104 reflects red light (R) of a polarized light flux emitted from the polarized-light illumination device 1100, and allows green light (G) and blue light (B) to pass through. The other dichroic mirror 1105 reflects the green light (G) passing through the dichroic mirror 1104, and allows the blue light (B) to pass through.

The red light (R) reflected by the dichroic mirror 1104 is reflected by the reflection mirror 1106 and then enters the liquid-crystal light valve 1210 via the relay lens 1205. The green light (G) reflected by the dichroic mirror 1105 enters the liquid-crystal light valve 1220 via the relay lens 1204. The blue light (B) passing through the dichroic mirror 1105 passes through a light guide system including the three relay lenses 1201, 1202, and 1203 and the two reflection mirrors 1107 and 1108, and then enters the liquid-crystal light valve 1230.

The liquid-crystal light valves 1210, 1220, and 1230 are each disposed so as to be opposed to a corresponding incident surface of each type of color light of the cross dichroic prism 1206. The color light that enters the liquid-crystal light valves 1210, 1220, and 1230 is modulated on the basis of image information (image signal), and is outputted toward the cross dichroic prism 1206.

In the cross dichroic prism 1206, four right-angle prisms are bonded together, and on inner surfaces of the prisms, a dielectric multilayer film configured to reflect the red light and a dielectric multilayer film configured to reflect the blue light are disposed in a cross shape. The three types of color light are synthesized by these dielectric multilayer films to obtain light representing a color image. The thus obtained light is projected onto a screen 1300 through the projection lens 1207 serving as a projection optical system, and an image is enlarged to be displayed.

The liquid crystal device 100 described above is applied to the liquid-crystal light valves 1210. The same applies to the other liquid-crystal light valves 1220 and 1230.

The projection-type display apparatus 1000 as described above includes the liquid crystal device 100 according to the first embodiment. This makes it possible to improve the reliability of electrical connecting in a region including the first contact hole CNT11, the second contact hole CNT12, and the third contact hole CNT13 of the element substrate 10. Furthermore, it is possible to suppress generation of heat within the element substrate 10. Note that it is possible to obtain the similar effects by employing the liquid crystal device according to the second embodiment as the liquid-crystal light valves 1210, 1220, and 1230.

In addition to the projection-type display apparatus 1000, the liquid crystal device 100 may be mounted on various types of electronic apparatuses such as an electrical view finder (EVF), a mobile mini-projector, a head-up display, a smartphone, a mobile phone, a mobile computer, a digital camera, a digital video camera, a display, a vehicle-mounted unit, an audio unit, a light exposure device, or an illumination unit.

What is claimed is:

1. An electro-optical device comprising:
a transistor;
a pixel electrode provided so as to correspond to the transistor;
a capacitance element provided so as to correspond to the pixel electrode;
a relay layer including a main body portion and a protruding portion, the main body portion extending along a first direction, the main body portion being electrically connected to the transistor through a first contact hole, the protruding portion protruding from the main body portion in a second direction intersecting the first direction, the protruding portion being electrically connected to the pixel electrode through a second contact hole, and
a first wiring line provided in a layer equal to the relay layer and including a main body portion and a protruding portion, the main body portion extending along the second direction, the protruding portion protruding from the main body portion in the first direction, the protruding portion being electrically connected to the capacitance element through a third contact hole, wherein
the relay layer and the first wiring line each includes a first layer having light reflectivity, and a second layer having light reflectance lower than the first layer and stacked at the first layer, and
the second layer is not provided in at least a portion of the main body portion of the first wiring line.

2. The electro-optical device according to claim 1 further comprising:
a second wiring line adjacent to the first wiring line, wherein
the relay layer is provided between the first wiring line and the second wiring line in plan view.

3. The electro-optical device according to claim 1, wherein
the second layer is not provided at a portion, at a side of the main body portion of the first wiring line, of the protruding portion of the first wiring line.

4. The electro-optical device according to claim 1, wherein
the second layer extends along the first direction, and is provided in the protruding portion of the first wiring line and a portion of the main body portion of the first wiring line.

5. The electro-optical device according to claim 1, wherein
the relay layer is configured such that the first layer and the second layer are provided in a region that overlaps with the first contact hole and the second contact hole in a planar view, and
the protruding portion of the first wiring line is configured such that the first layer and the second layer are provided in a region that overlaps with the third contact hole in a planar view.

6. The electro-optical device according to claim 1, wherein
the first layer includes aluminum, and
the second layer includes titanium nitride.

7. An electronic apparatus comprising the electro-optical device according to claim 1.
